(19) United States
(12) Patent Application Publication
(10) Pub. No.: US 2006/0097377 A1
(43) Pub. Date: May 11, 2006

(54) Flip chip bonding structure using non-conductive adhesive and related fabrication method

(76) Inventor: Han-Shin Youn, Chungcheongnam-do (KR)

Correspondence Address: MARGER JOHNSON & McCOLLOM, P.C., 1030 S.W. Morrison Street, Portland, OR, 97205, US

(21) Appl. No.: 11/270,431

(22) Filed: Nov. 8, 2005

(30) Foreign Application Priority Data
Nov. 9, 2004 (KR) 2004-90667

(51) Int. Cl. H01L 23/52

(52) U.S. Cl. 257/692

(57) ABSTRACT

A flip chip bonding structure has a non-conductive adhesive interposed between an integrated circuit (IC) chip and a circuit substrate. The IC chip has I/O pads on an active surface thereof, and the circuit substrate has bump pads on a first surface thereof. The non-conductive adhesive is provided on the active surface of the chip or alternatively on the first surface of the substrate, exposing the I/O pads or the bump pads respectively. Conductive bumps such as metal bumps are formed on the I/O pads and then bonded to the bump pads. With no adhesive between the metal bumps and the bump pads, non-conductive particles in the adhesive do not obstruct mechanical and electrical connections therebetween. The particle content of the non-conductive adhesive can be increased and flip chip bonding structures can be formed in a wafer level process.

### CROSS REFERENCE TO RELATED APPLICATIONS

This U.S. non-provisional application claims benefit of priority under 35 U.S.C. §119 of Korean Patent Application No. 2004-90667, filed on Nov. 9, 2004, the entire contents of which are incorporated herein by reference.

### BACKGROUND OF THE INVENTION

1. Field of the Invention

The present invention relates generally to semiconductor package technology and, more particularly, to a flip chip bonding structure using a non-conductive adhesive and a related fabrication method.

2. Description of the Related Art

As is well known, a great number of integrated circuit (IC) devices are simultaneously fabricated in a silicon wafer and divided into individual IC chips. Each IC chip is then separated from the wafer and assembled in a package to form an electronic product. The package may include a structure to physically support the chip, a physical housing to protect the chip from the environment, an adequate means of dissipating heat generated by the chip, and electrical connections allowing signal and power access to and from the chip. Package technology is important because it can affect the price, performance, and reliability of final products.

Flip chip bonding technology allows direct electrical connection of a face-down (hence, “flipped”) chip onto a package substrate by means of conductive bumps formed on chip pads. In contrast, wire bonding, an old technology, uses a face-up chip with a wire connection to each pad. Flip chip bonding has the potential for smaller package size, higher electrical performance, greater input/output (I/O) connection flexibility, and so forth over other bonding technologies such as wire bonding. In recent years flip chip bonding technology has made further progress due to the advent of wafer level packaging (WLP) technology.

One of the packaging methods related to flip chip bonding technology is the use of a non-conductive adhesive. FIGS. 1A to 1C show cross-sectional views of a conventional flip chip bonding structure using a non-conductive adhesive, and a fabrication method thereof.

Referring to FIG. 1A, a circuit substrate 11 has a number of bump pads 12 arranged regularly on a first surface 11a. A non-conductive adhesive 13 covers the first surface 11a of the circuit substrate 11. Typically, the non-conductive adhesive 13 is in the form of film or curable paste.

As shown in FIG. 1B, an IC chip 14 lies face-to-face with the non-conductive adhesive 13. The IC chip 14 has a number of I/O pads 15 arranged regularly on an active surface 14a. A number of metal bumps 16 are formed on the respective I/O pads 15. The active surface 14a of the IC chip 14 faces toward the circuit substrate 11 as covered with the non-conductive adhesive 13.

As shown in FIG. 1C, the IC chip 14 is engages and attaches to the non-conductive adhesive 13. At this time the metal bumps 16 are mechanically joined to or contacting the corresponding bump pads 12, pushing out the adhesive 13. The IC chip 14 is thereby electrically coupled to the circuit substrate 11 through the metal bumps 16, and a flip chip bonding structure 10 is obtained. Thereafter, to complete a flip chip package, solder balls (not shown) for external connections are provided on a second surface 11b of the circuit substrate 11.

As described above, in the conventional flip chip bonding structure 10, the metal bumps 16 are pushed into the non-conductive adhesive 13 to meet the bump pads 12. Typically, the non-conductive adhesive 13 is composed of resin and non-conductive particles mixed together. When the metal bumps 16 push the adhesive 13, the resin is easily pushed by the metal bumps 16, however the non-conductive particles are not easily pushed. Such particles remaining between the metal bumps 16 and the bump pads 12 may cause mechanically and electrically poor connections.

For this reason, the content of the particles in the non-conductive adhesive 13 is limited to 50% or below. However, since the particles give a required strength and stability to the adhesive 13, low particle content may unfavorably affect the reliability of the adhesive 13 and, therefore, affect the reliability of flip chip structure 10 generally.

Additionally, attaching the metal bumps 16 to the bump pads 12 by pushing away the non-conductive adhesive 13 is difficult to perform at wafer level. Thus, conventional flip chip bonding structures could require fabrication at individual chip level. Undesirably, this could result in reduced productivity and/or higher cost.

### SUMMARY OF THE INVENTION

Example, non-limiting embodiments of the present invention provide a flip chip bonding structure allowing improved mechanical and electrical connections in spite of increased particle content of a non-conductive adhesive. Furthermore, example embodiments of the present invention provide a method of fabricating a flip chip bonding structure at wafer level.

According to an example embodiment of the present invention, the flip chip bonding structure comprises an integrated circuit (IC) chip, a circuit substrate, a non-conductive adhesive, and a number of metal bumps. The IC chip has a number of input/output (I/O) pads arranged on an active surface thereof. The circuit substrate has a number of bump pads arranged on a first surface thereof. The non-conductive adhesive is provided on the active surface of the IC chip and exposes the I/O pads of the IC chip. The metal bumps are formed on the I/O pads of the IC chip and bonded to the corresponding bump pads of the circuit substrate.

According to another example embodiment of the present invention, the flip chip bonding structure comprises an integrated circuit (IC) chip, a circuit substrate, a non-conductive adhesive, and a number of metal bumps. The IC chip has a number of input/output (I/O) pads arranged on an active surface thereof. The circuit substrate has a number of bump pads arranged on a first surface thereof. The non-conductive adhesive is applied onto the first surface of the circuit substrate and exposes the bump pads of the circuit substrate. The metal bumps are formed on the I/O pads of the IC chip and bonded to the corresponding bump pads of the circuit substrate.

In the flip chip bonding structure of the present invention, the non-conductive adhesive may be in the form of film or curable adhesive. Further, the adhesive may include resin and non-conductive particles mixed together. The resin may be made of epoxy or silicone. The non-conductive particles may be made of silicon dioxide (SiO₂) or silicon carbide (SiC).

In the flip chip bonding structure of the present invention, the circuit substrate may further have a solder mask covering the first surface and exposing the bump pads. The solder mask may have windows each of which exposes one of the bump pads. Alternatively, the solder mask may have windows each of which exposes a row of the bump pads.

In the flip chip bonding structure of the present invention, the circuit substrate may further include a number of ball pads arranged on a second surface, opposite to the first surface. Additionally, the structure may further comprise a number of solder balls each formed on one ball pad of the circuit substrate.

According to another example embodiment of the present invention, a method of fabricating a flip chip bonding structure comprises providing an integrated circuit (IC) chip having a number of input/output (I/O) pads arranged on an active surface thereof. The method also comprises providing a non-conductive adhesive on the active surface of the IC chip, partly removing the non-conductive adhesive so as to expose the I/O pads of the IC chip, and forming a number of metal bumps on the I/O pads of the IC chip. The method further comprises providing a circuit substrate having a number of bump pads arranged on a first surface thereof, and bonding the metal bumps to the corresponding bump pads of the circuit substrate.

According to another example embodiment of the present invention, a method of fabricating a flip chip bonding structure comprises providing an integrated circuit (IC) chip having a number of input/output (I/O) pads arranged on an active surface thereof. The method also comprises forming a number of metal bumps on the I/O pads of the IC chip, and providing a circuit substrate having a number of bump pads arranged on a first surface thereof. The method further comprises providing a non-conductive adhesive on the first surface of the circuit substrate, exposing the bump pads out of the non-conductive adhesive, and bonding the metal bumps to the corresponding bump pads of the circuit substrate.

In the fabrication method of the present invention, the step of providing the IC chip may include providing a wafer having a number of the individual IC chips. The method may further comprise sawing the wafer to separate the individual IC chips from the wafer, before or after the bonding of the metal bumps.

In the fabrication method of the present invention, the metal bumps may be formed to have a height greater than the thickness of the non-conductive adhesive. The step of providing the circuit substrate may include forming a solder mask to cover the first surface, and forming windows in the solder mask to expose the bump pads. The step of bonding the metal bumps may include inserting the metal bumps into the windows of the solder mask.

### BRIEF DESCRIPTION OF THE DRAWINGS

FIGS. 1A to 1C are cross-sectional views showing a conventional flip chip bonding structure using a non-conductive adhesive and a fabrication method thereof.

FIGS. 2 to 9 show a flip chip structure and a fabrication method thereof in accordance with an example embodiment of the present invention, wherein:

FIG. 2 is a plan view showing a wafer and an individual IC chip;

FIG. 3A is a plan view showing a non-conductive adhesive on the IC chip;

FIG. 3B is a cross-sectional view taken along the line IIIB-IIIB of FIG. 3A;

FIG. 4A is a plan view showing the non-conductive adhesive partly removed for exposing I/O pads on the IC chip;

FIG. 4B is a cross-sectional view taken along the line IVB-IVB of FIG. 4A;

FIG. 5A is a plan view showing metal bumps provided on the I/O pads;

FIG. 5B is a cross-sectional view taken along the line VB-VB of FIG. 5A;

FIG. 6A is a plan view showing a first surface of a circuit substrate;

FIG. 6B is a plan view showing a second surface of the circuit substrate;

FIG. 7 is a plan view showing a first surface of an alternative circuit substrate;

FIG. 8A is a cross-sectional view showing a structure before flip chip bonding;

FIG. 8B is a cross-sectional view showing a structure after flip chip bonding; and

FIG. 9 is a cross-sectional view showing solder balls on the second surface of the circuit substrate.

FIGS. 10A and 10B are cross-sectional views showing a flip chip structure and a fabrication method thereof in accordance with another example embodiment of the present invention.

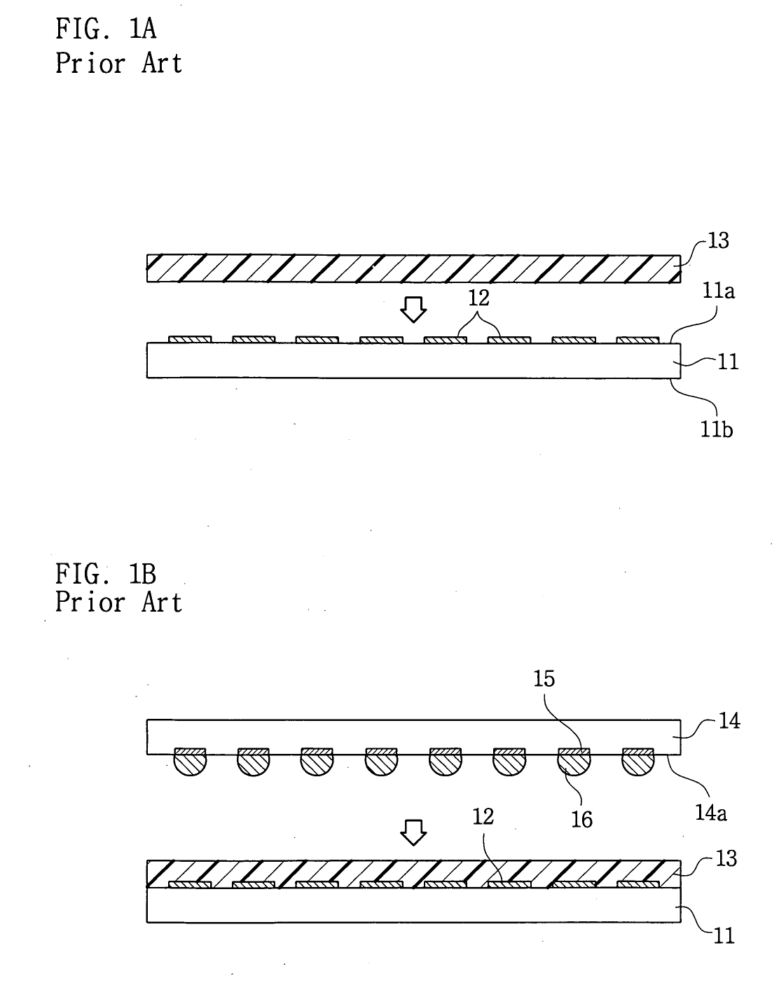

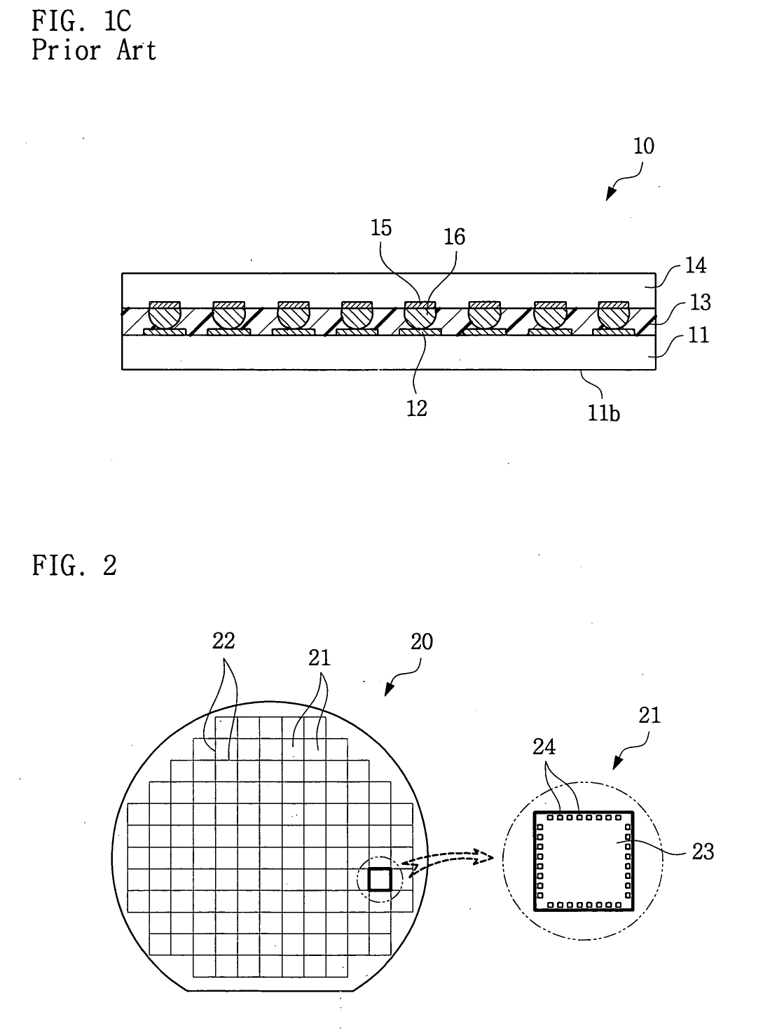

### DETAILED DESCRIPTION OF EXAMPLE EMBODIMENTS OF THE INVENTION

Example, non-limiting embodiments of the present invention will now be described more fully hereinafter with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and feature of this invention may be employed in varied and numerous embodiments without departing from the scope of the invention.

In this disclosure, well-known structures and processes are not described or illustrated in detail to avoid obscuring the present invention. Furthermore, the figures in the drawings are not drawn to scale. Rather, for simplicity and clarity of illustration, the dimensions of some of the elements are exaggerated relative to other elements. Like reference numerals are used for like and corresponding parts of the various drawings.

FIGS. 2 to 9 show in sequence a method of fabricating a flip chip bonding structure in accordance with an example embodiment of the present invention. The flip chip bonding structure may be fabricated from an individual IC chip, but such structures may also be simultaneously fabricated from a wafer of IC chips to increase productivity and reduce cost.

FIG. 2 shows, in a plan view, a wafer 20 and an individual IC chip 21.

Referring to FIG. 2, the wafer 20 includes a large number of the IC chips 21, which are divided from each other by scribe lanes 22 running crosswise. Each IC chip 21 has a number of I/O pads 24 arranged along a peripheral region on an active surface 23. The active surface 23 is typically covered with a passivation layer for protecting internal circuits of the chips, and the I/O pads 24 are exposed externally through the passivation layer. The I/O pads 24 may be alternatively arranged along a central line on the active surface 23. It will be appreciated, however, that the above arrangements of the I/O pads 24 are presented for the purpose of illustration only, and not as a limitation of the invention.

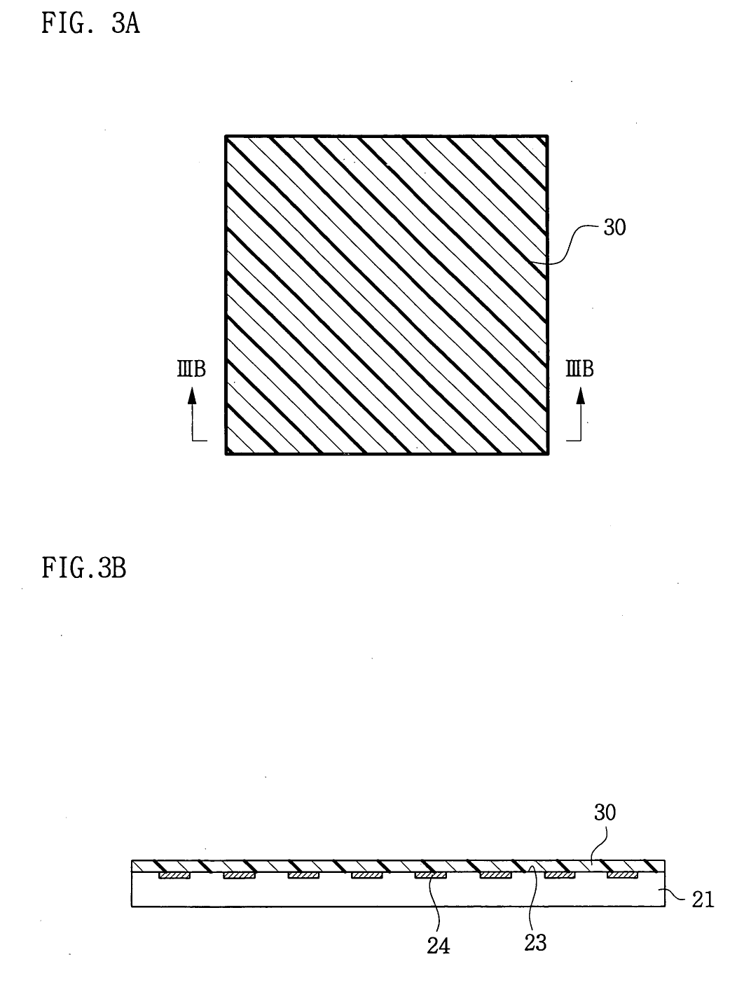

FIG. 3A shows a plan view of a non-conductive adhesive 30 on the IC chip 21. FIG. 3B is a cross-sectional view taken along the line IIIB-IIIB of FIG. 3A.

Referring to FIGS. 3A and 3B, the non-conductive adhesive 30 is provided on the entire active surface 23 of the IC chip 21. The non-conductive adhesive 30 is composed of resin and non-conductive particles mixed together, and is in the form of film or curable paste. The resin constituting the adhesive 30 may be epoxy, silicone, or other polymeric materials. The non-conductive particles mixed in the resin may be silicon dioxide (SiO₂), silicon carbide (SiC), or other solid particles.

If the adhesive 30 is a film type, it may be directly attached to the active surface 23. If the adhesive 30 is a paste type, it may be applied onto the active surface 23. Contrary to the aforementioned conventional art, the non-conductive adhesive 30 of the invention may include the particles in a content of 80% or more. Further, it may be possible to provide the adhesive 30 onto the entire wafer.

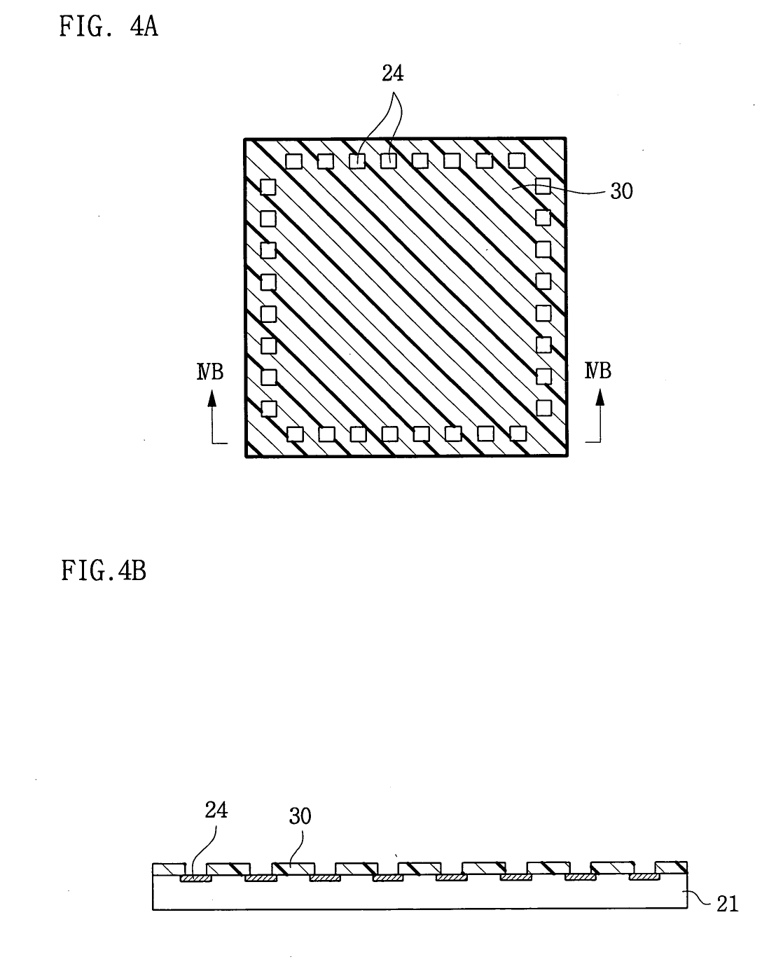

FIG. 4A shows, in a plan view, the non-conductive adhesive 30 partly removed for exposing the I/O pads 24 on the IC chip 21. Further, FIG. 4B is a cross-sectional view taken along the line IVB-IVB of FIG. 4A.

As shown in FIGS. 4A and 4B, the non-conductive adhesive 30 is partly removed such that the I/O pads 24 are exposed externally. The partial removal of the adhesive 30 may be carried out by means of a typical selective etching process using a patterned photoresist mask.

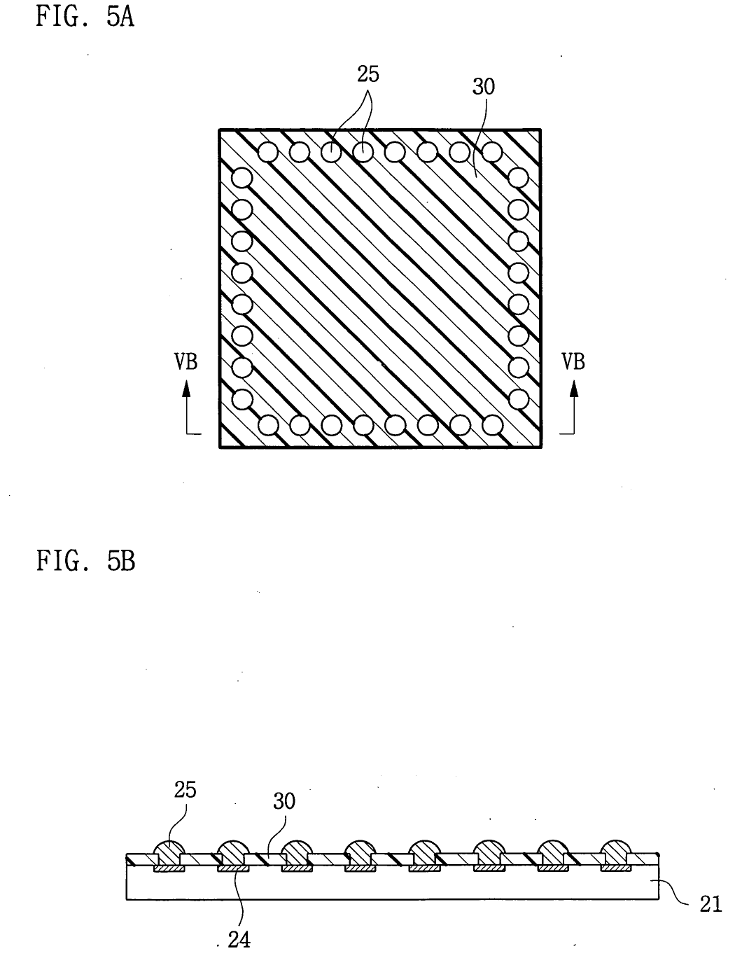

FIG. 5A shows a plan view of metal bumps 25 provided on the I/O pads 24. FIG. 5B is a cross-sectional view taken along the line VB-VB of FIG. 5A.

As shown in FIGS. 5A and 5B, the metal bumps 25 are formed on the exposed I/O pads 24. During this step, the adhesive 30 is employed as a mask for the metal bumps 25. The metal bumps 25 have a height greater than the thickness of the adhesive 30, so the bumps 25 may have a mushroom shape. The bumps 25 may be formed using well-known technology, for example (but not limited to) sputtering, electroplating, stencil plating, and stud bumping. Further, the bumps 25 may be made of solder or gold. It will be appreciated that the disclosed technologies and materials for forming the bumps 25 are examples only and not to be considered as limitations of example embodiments of the invention.

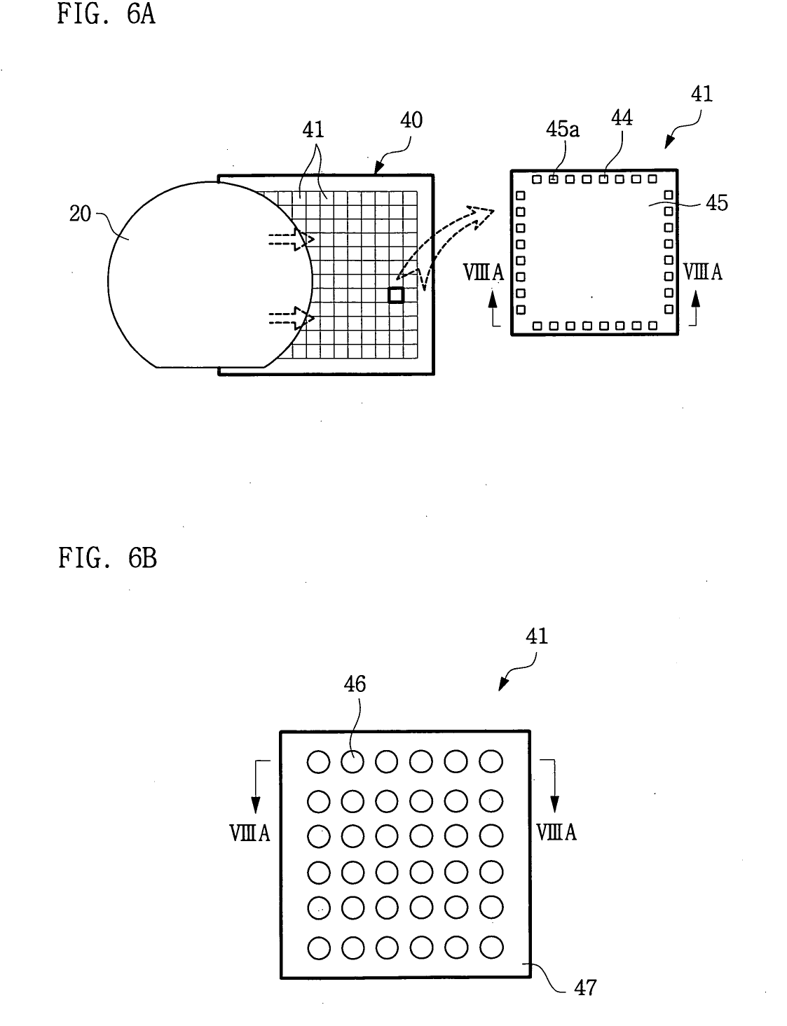

FIGS. 6A and 6B show plan views of a first surface and a second surface, respectively, of a circuit substrate 41.

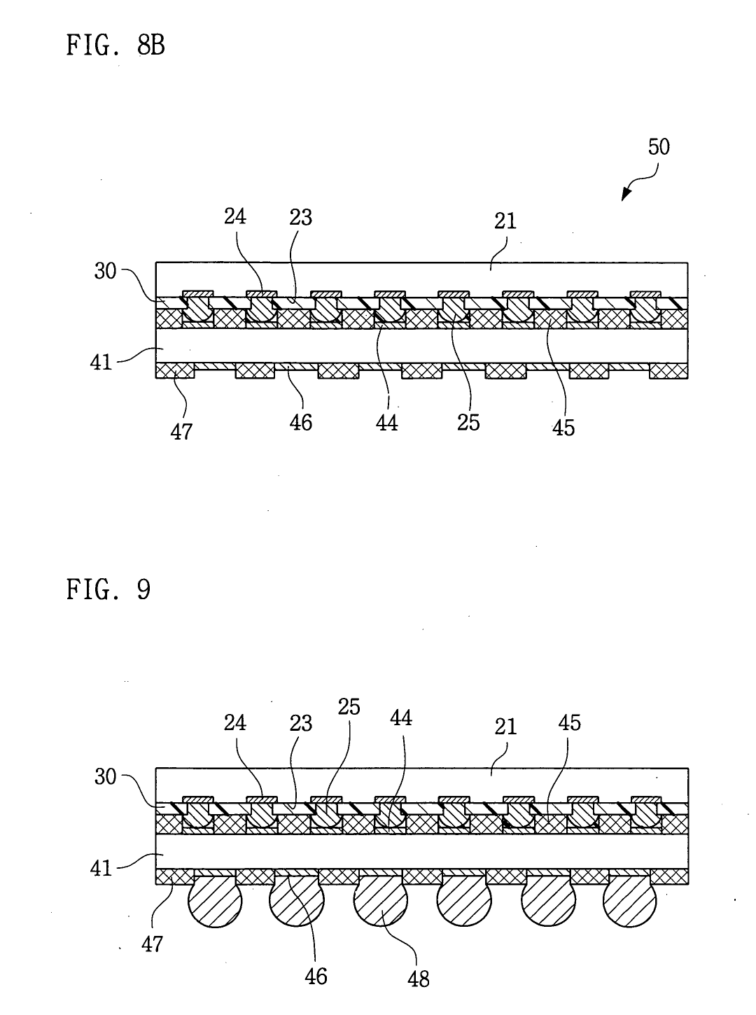

Referring to FIG. 6A, the circuit substrate 41 is fabricated from a substrate matrix 40, which includes a large number of the circuit substrates 41. The substrate matrix 40 may allow the flip chip bonding structure of the present invention to be fabricated at wafer level. Each individual circuit substrate 41 of the substrate matrix 40 corresponds to an individual IC chip 21 of the wafer 20 described above. The circuit substrate 41 may have well known circuit layer structures such as single-layer, two-layer, or multi-layer. The circuit substrate 41 has the first surface 42 (shown in FIGS. 6A and 8A) and the second surface 43 (shown in FIGS. 6B and 8A). The configuration of the circuit substrate 41 is shown in FIG. 8A taken as a cross-sectional view along the line VIIIA-VIIIA of FIGS. 6A and 6B.

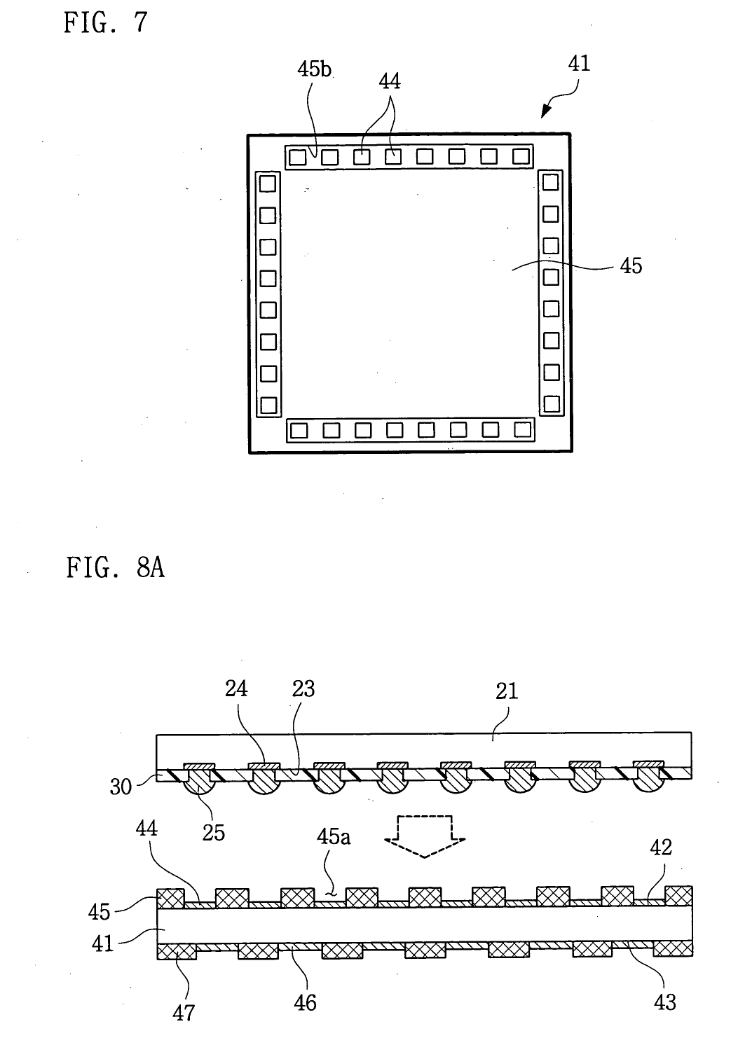

As shown in FIGS. 6A and 8A, a number of bump pads 44 are arranged on the first surface 42 of the circuit substrate 41. Excepting the bump pads 44, the first surface 42 is covered with and protected by a solder mask 45. The arrangement of the bump pads 44 corresponds to the above-described bump and I/O pad arrangement. The solder mask 45 has windows 45a through which the bump pads 44 are exposed one by one. The windows 45a may vary in shape as shown, for example, by alternative windows 45b in FIG. 7.

FIG. 7 shows a plan view of the first surface of an alternative circuit substrate 41. Referring to FIG. 7, the alternative windows 45b of the solder mask 45 are formed in a shape of four grooves, each of which completely exposes a row of the bump pads 44. This shape of the windows 45b may be favorable for the closely spaced bump pads 44.

Referring to FIGS. 6B and 8A, the second surface 43 of the circuit substrate 41 has a number of ball pads 46 arranged thereon. Excepting the ball pads 46, the second surface 43 is covered with and protected by a solder mask 47. The ball pads 46 have a relatively large size in comparison to the bump pad 44, and are evenly distributed over the entire second surface 43. It is therefore possible to increase the size of the ball pad 46 relative that of the bump pad 44.

FIGS. 8A and 8B show cross-sectional views of structures before and after flip chip bonding, respectively. Although FIGS. 8A and 8B depict the bonding process of only the individual IC chip 21 for clarity, such a bonding process may also be applied to the entire surface of the wafer.

Referring to FIG. 8A, the flip chip bonding process is implemented in a state that the active surface 23 of the IC chip 21 faces towards the first surface 42 of the circuit substrate 41. The metal bumps 25 on the active surface 23 are then inserted into the corresponding windows 45a of the solder mask 45 on the first surface 42.

When proper heat and pressure are applied to the IC chip 21 and the circuit substrate 41, the metal bumps 25 and the bump pads 44 are mechanically joined to each other by thermocompression, as shown in FIG. 8B. The IC chip 21 is therefore electrically coupled to the circuit substrate 41 through the metal bumps 25, and a flip chip bonding structure 50 is obtained.

During the flip chip bonding process, the non-conductive adhesive 30 flows into and fills the windows 45a of the solder mask 45. The non-conductive adhesive 30 is not, however, interposed between the metal bumps 25 and the bump pads 44. Therefore, the non-conductive particles in the adhesive 30 do not obstruct the mechanical and electrical connections between the bumps 25 and the bump pads 44. Moreover, since a reason for limiting the particle content is eliminated, it is therefore possible to increase the particle content of the non-conductive adhesive 30, and thereby to enhance the strength, stability and reliability of the non-conductive adhesive 30. The content of the non-conductive particles may be increased to 80% or more.

FIG. 9 shows a cross-sectional view of solder balls 48 on the second surface 43 of the circuit substrate 41. As shown in FIG. 9, the solder balls 48 are formed on the ball pads 46, which are arranged on the second surface 43 of the circuit substrate 41. The solder balls 48 provide terminals for external connection to the flip chip structure, and thereby a flip chip package is completed. The solder balls 48 may be formed using well-known solder ball attaching technology or another suitable technology. The solder balls 48 may be made of typical solder material of 63% tin (Sn) and 37% lead (Pb), lead-free solder, or any other suitable solder materials well known in the art.

Before forming the solder balls 48, a typical marking process may be carried out using laser or ink as well known in the art. After forming the solder balls 48, the wafer (20 in FIG. 2) is sawed along the scribe lanes (22 in FIG. 2) in the well-known wafer sawing process. In the wafer sawing process, the circuit substrate 41 and the adhesive 30 are simultaneously cut together with the IC chip 21, and the individual packages are then separated from the wafer. The wafer sawing process may be performed using a well-known punch or rotating blade. If flip chip bonding as described herein is performed on the individual IC chips, the wafer sawing process is performed before the flip chip bonding process.

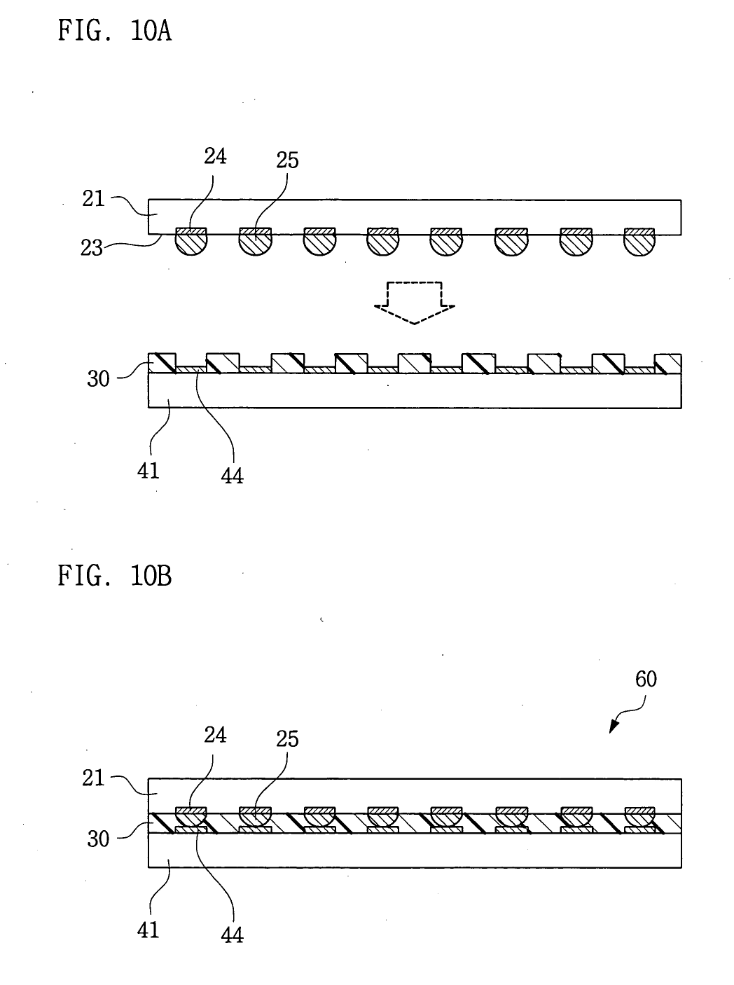

The above-described example embodiment of the invention uses a method of applying the non-conductive adhesive 30 to the IC chip 21, whereas an alternative example embodiment may use a method of applying the non-conductive adhesive to the circuit substrate 41. FIGS. 10A and 10B show cross-sectional views of a flip chip structure and a fabrication method thereof in accordance with another example embodiment of the present invention.

Referring to FIG. 10A, the non-conductive adhesive 30 is formed on the first surface 42 of the circuit substrate 41 and partly removed to expose the bump pads 44. The adhesive 30 may replace the aforementioned solder mask on the first surface, or be alternatively formed on the solder mask. The active surface 23 of the IC chip 21 has the metal bumps 25 formed on the I/O pads 24. The flip chip bonding process is implemented in a state that the active surface 23 of the IC chip 21 faces towards the first surface 42 of the circuit substrate 41. The metal bumps 25 on the active surface 23 are then inserted into the partly removed spaces of the adhesive 30 on the circuit substrate 41.

Referring to FIG. 10B, by applying proper heat and pressure to the IC chip 21 and the circuit substrate 41, the metal bumps 25 and the bump pads 44 are mechanically joined to each other by thermocompression. The IC chip 21 is therefore electrically coupled to the circuit substrate 41 through the metal bumps 25, and a flip chip bonding structure 60 is obtained. Thereafter, although not shown in FIGS. 10A and 10B, solder balls may be formed on the ball pads that are arranged on the second surface of the circuit substrate 41 and exposed through the solder mask.

The non-conductive adhesive 30 may flow during the flip chip bonding process, so a gap between the IC chip 21 and the circuit substrate 41 is fully filled with the adhesive 30. As in the previous embodiment, the non-conductive adhesive 30 in this embodiment is not interposed between the metal bumps 25 and the bump pads 44. Therefore, the non-conductive particles in the adhesive 30 do not obstruct the mechanical and electrical connections between the bumps 25 and the bump pads 44. Moreover, since a reason for limiting the particle content is eliminated, it is therefore possible to increase the particle content of the adhesive 30, and thereby to enhance the strength, stability and reliability of the adhesive 30. The content of the non-conductive particles may be increased to 80% or more.

While this invention has been particularly shown and described with reference to example embodiments thereof, it will be understood by those skilled in the art that various changes in form and details may be made therein without departing from the spirit and scope of the invention as defined by the appended claims.

What is claimed is:

1. A flip chip bonding structure comprising:
an integrated circuit chip having a plurality of input/output pads arranged on an active surface thereof;
a circuit substrate having a plurality of bump pads arranged on a first surface thereof;
a non-conductive adhesive provided on the active surface of the IC chip and exposing the input/output pads of the integrated circuit chip; and
a plurality of metal bumps formed on the input/output pads of the IC chip and bonded to corresponding ones of the plurality of bump pads.

2. The structure of claim 1, wherein the non-conductive adhesive is in the form of a form of film or curable adhesive.

3. The structure of claim 1, wherein the non-conductive adhesive includes resin and non-conductive particles mixed therein.

4. The structure of claim 3, wherein the resin of the non-conductive adhesive is made of at least one of an epoxy and a silicone.

5. The structure of claim 3, wherein the non-conductive particles of the non-conductive adhesive are made of at least one of a silicon dioxide (SiO₂) and a silicon carbide (SiC).

6. The structure of claim 1, wherein the circuit substrate further comprises a solder mask covering the first surface and exposing the bump pads.

7. The structure of claim 6, wherein the solder mask includes windows, each of the windows exposing one of the bump pads.

8. The structure of claim 6, wherein the solder mask includes windows, each of the windows exposing at least two of the bump pads.

9. The structure of claim 1, wherein the circuit substrate further includes a plurality of ball pads arranged on a second surface opposite to the first surface.

10. The structure of claim 9, further comprising:
a plurality of solder balls each formed on one of the plurality of ball pads.

11. A flip chip bonding structure comprising:
an integrated circuit chip having a plurality of input/output pads arranged on an active surface thereof;
a circuit substrate having a plurality of bump pads arranged on a first surface thereof;
a non-conductive adhesive provided on the first surface of the circuit substrate and exposing the bump pads of the circuit substrate; and
a plurality of metal bumps formed on the input/output pads of the integrated circuit chip and bonded to the corresponding bump pads of the circuit substrate.

12. The structure of claim 11, wherein the non-conductive adhesive is in the form of film or curable adhesive.

13. The structure of claim 11, wherein the non-conductive adhesive includes resin and non-conductive particles mixed together.

14. The structure of claim 13, wherein the resin of the non-conductive adhesive comprises at least one of epoxy and silicone.

15. The structure of claim 13, wherein the non-conductive particles of the non-conductive adhesive comprise at least one of silicon dioxide (SiO₂) and silicon carbide (SiC).

16. The structure of claim 11, wherein the circuit substrate further includes a plurality of ball pads arranged on a second surface thereof opposite to the first surface.

17. The structure of claim 16, further comprising:
a plurality of solder balls each formed on a corresponding ball pad of the circuit substrate.

18. A method of fabricating a flip chip bonding structure, the method comprising:
providing an integrated circuit chip having a plurality of input/output pads arranged on an active surface thereof;
providing a non-conductive adhesive on the active surface of the integrated circuit chip;
removing a portion of the non-conductive adhesive to expose the input/output pads of the integrated circuit chip;
forming a plurality of conductive bumps on the input/output pads of the integrated circuit chip;
providing a circuit substrate having a plurality of bump pads arranged on a first surface thereof and corresponding to the plurality of bump pads; and
bonding the conductive bumps to the corresponding bump pads of the circuit substrate.

19. The method of claim 18, wherein the step of providing the integrated circuit chip includes providing a wafer comprising a plurality of integrated chips.

20. The method of claim 19, further comprising:
sawing the wafer to separate the plurality of integrated circuit chips after the bonding of the conductive bumps.

21. The method of claim 19, further comprising:
sawing the wafer to separate the plurality of integrated circuit chips before the bonding of the conductive bumps.

22. The method of claim 18, wherein a height of the conductive bumps is greater than a thickness of the non-conductive adhesive.

23. The method of claim 18, wherein providing the circuit substrate includes forming a solder mask to cover the first surface and forming windows in the solder mask to expose the bump pads.

24. The method of claim 23, wherein bonding the conductive bumps includes inserting the conductive bumps into the windows of the solder mask.

25. A method of fabricating a flip chip bonding structure, the method comprising:
providing an integrated circuit chip having a plurality of input/output pads arranged on an active surface thereof;
forming a plurality of conductive bumps on the input/output pads of the integrated circuit chip;
providing a circuit substrate having a plurality of bump pads arranged on a first surface thereof;
providing a non-conductive adhesive on the first surface of the circuit substrate, the non-conductive adhesive exposing the bump pads; and
bonding the conductive bumps to corresponding bump pads of the circuit substrate.

26. The method of claim 25, wherein the step of providing the integrated circuit chip includes providing a wafer having a plurality of integrated circuit chips.

27. The method of claim 26, further comprising:
sawing the wafer to separate the plurality of integrated circuit chips after bonding of the conductive bumps.

28. The method of claim 26, further comprising:
sawing the wafer to separate the plurality of integrated circuit chips before the bonding of the conductive bumps.

29. A method of fabricating a flip chip bonding structure, the method comprising:
providing an integrated circuit chip having on an active side thereof a plurality of chip pads arranged according to a given pattern;
providing a circuit substrate having on one side thereof a plurality of substrate pads arranged according to the given pattern to correspond with the chip pads;
providing a non-conductive adhesive having therethrough a plurality of apertures arranged according to the given pattern to correspond to the chip pads and to the substrate pads;
arranging the active surface of the integrated circuit in face-to-face relation with the one side of the circuit substrate and with the non-conductive adhesive therebetween whereby selected chip pads lie face-to-face with corresponding substrate pads through a corresponding aperture; and
electrically coupling the selected chip pads and the corresponding substrate pads.

30. A method according to claim 29, wherein electrically coupling includes interposing between corresponding chip pads and substrate pads electrically conductive bumps.

31. A method according to claim 30, wherein the bumps are first bonded to the chip pads and thereafter inserted into corresponding apertures.

32. A method according to claim 30, wherein the bumps are first bonded to the substrate pads and thereafter inserted into corresponding apertures.

33. A method according to claim 30, wherein a height of the bumps is greater than a thickness of the non-conductive adhesive.

34. A method according to claim 29, wherein providing a non-conductive adhesive includes etching to form the plurality of apertures.

35. A method according to claim 34, wherein the method further includes first attaching the non-conductive adhesive to the integrated circuit chip and thereafter forming the apertures.

36. A method according to claim 34, wherein the method further includes first attaching the non-conductive adhesive to the circuit substrate and thereafter forming the apertures.

37. A method according to claim 29, wherein the integrated circuit chip is one of a plurality of chips forming a wafer and the circuit substrate is one of a corresponding plurality of circuit substrates forming a substrate matrix.

38. A method according to claim 37, wherein the wafer and the matrix are arranged in face-to-face relation with the non-conductive adhesive therebetween.

39. A method according to claim 38, wherein the bumps are attached to one of the wafer and the matrix and thereafter inserted into corresponding apertures to electrically couple the chip pads with corresponding substrate pads.

40. A method according to claim 37, further comprising:
bonding conductive bumps to the chip pads; and
sawing the wafer to separate the plurality of integrated circuit chips after the bonding of the conductive bumps thereto.

41. A method according to claim 37, further comprising:
bonding conductive bumps to the substrate pads; and
sawing the matrix to separate the plurality of circuit substrates before the bonding of the conductive bumps thereto.

42. A method according to claim 29, wherein providing the circuit substrate includes forming a solder mask to cover the first surface and forming windows in the solder mask to expose the substrate pads.

43. A method according to claim 42, further comprising:
bonding conductive bumps to one of the plurality of chip pads and the plurality of substrate pads; and
inserting the conductive bumps into the windows of the solder mask.

44. In flip chip bonding structure manufacture, the flip chip bonding structure including an integrated chip having an active surface in face-to-face relation with a circuit substrate and having a non-conductive adhesive and a plurality of conductive bumps interposed between the integrated circuit chip and the circuit substrate, the active surface having a plurality of chip pads, the circuit substrate having a corresponding plurality of substrate pads positioned to contact corresponding bumps therebetween, an improvement comprising:
bonding the plurality bumps to selected ones of the plurality of chip pads and the plurality of substrate pads;
providing a plurality of apertures in the non-conductive adhesive, the apertures corresponding to the plurality of chip pads and to the plurality of substrate pads; and
inserting the bumps into corresponding ones of the apertures to electrically couple ones of the plurality of chip pads with corresponding ones of the plurality of substrate pads.

45. A flip chip bonding structure in assembly comprising:
an integrated circuit chip having a plurality of chip pads on an active surface thereof;
a circuit substrate having a plurality of substrate pads on a first surface thereof;
a plurality of bumps; and
a non-conductive adhesive having a plurality of apertures therethrough, the plurality of chip pads, the plurality of substrate pads, the plurality of bumps, and the plurality of apertures corresponding according to a given pattern, each bump being interposed between corresponding chip pads and substrate pads and positioned to enter a corresponding aperture to electrically couple chip pads with corresponding substrate pads.
